(19) United States
(12) Patent Application Publication
(10) Pub. No.: US 2025/0260383 A1
(43) Pub. Date: Aug. 14, 2025

(54) ACOUSTIC WAVE DEVICE

(71) Applicant: Murata Manufacturing Co., Ltd., Nagaokakyo-shi (JP)

(72) Inventor: Hiromu OKUNAGA, Nagaokakyo-shi (JP)

(21) Appl. No.: 19/192,593

(22) Filed: Apr. 29, 2025

Related U.S. Application Data
(63) Continuation of application No. PCT/JP2023/037730, filed on Oct. 18, 2023.

(30) Foreign Application Priority Data
Nov. 14, 2022 (JP) 2022-181787

(51) Int. Cl. H03H 9/25; H03H 9/02; H03H 9/145

(52) U.S. Cl. CPC H03H 9/25; H03H 9/02559; H03H 9/145

(57) ABSTRACT

An acoustic wave device includes a piezoelectric substrate including a piezoelectric layer and a functional electrode on the piezoelectric layer and including electrode fingers. The piezoelectric layer includes at least a first region and a second region with crystal orientations different from each other. The functional electrode overlaps the first region and the second region in plan view.

### CROSS REFERENCE TO RELATED APPLICATIONS

This application claims the benefit of priority to Japanese Patent Application No. 2022-181787 filed on Nov. 14, 2022 and is a Continuation Application of PCT Application No. PCT/JP2023/037730 filed on Oct. 18, 2023. The entire contents of each application are hereby incorporated herein by reference.

### BACKGROUND OF THE INVENTION

### 1. Field of the Invention

The present invention relates to acoustic wave devices.

### 2. Description of the Related Art

Acoustic wave devices have been widely used for filters of cellular phones and the like. Japanese Unexamined Patent Application Publication No. 2013-009173 discloses an example of a surface acoustic wave device. In the surface acoustic wave device, a crystal orientation adjustment film is disposed on a portion of a substrate. A piezoelectric thin film is disposed on the substrate over a portion where the crystal orientation adjustment film is provided and a portion where no crystal orientation adjustment film is provided. Consequently, regarding the piezoelectric thin film, the directions of c-axes of the portion disposed on the crystal orientation adjustment film and the portion not disposed on the crystal orientation adjustment film differ from each other. A comb-shaped electrode is disposed on each of the portions of the piezoelectric thin film having c-axis directions that differ from each other. Consequently, a resonator is formed on each of the portions of the piezoelectric thin film having c-axis directions that differ from each other.

In the surface acoustic wave device described in Japanese Unexamined Patent Application Publication No. 2013-009173, a resonator is independently formed on each of the portions of the piezoelectric thin film having c-axis directions that differ from each other. However, fractional band widths of these resonators are not readily adjusted.

### SUMMARY OF THE INVENTION

Example embodiments of the present invention provide acoustic wave devices each able to readily adjust a fractional band width.

An acoustic wave device according to an example embodiment of the present invention includes a piezoelectric substrate including a piezoelectric layer, and a functional electrode on the piezoelectric layer and including a plurality of electrode fingers. The piezoelectric layer includes at least a first region and a second region with crystal orientations different from each other, and the functional electrode overlaps the first region and the second region in plan view.

An acoustic wave device according to another example embodiment of the present invention includes a piezoelectric substrate including a piezoelectric layer, and a functional electrode at least a portion of which is embedded in the piezoelectric substrate. The piezoelectric substrate includes at least a first region and a second region with crystal orientations different from each other, and the piezoelectric layer includes at least one of the first region and the second region.

An acoustic wave device according to another example embodiment of the present invention includes a piezoelectric substrate including a piezoelectric layer, and a functional electrode on the piezoelectric layer and including a plurality of electrode fingers. The piezoelectric layer includes at least a first region and a second region with crystal structures different from each other, and the functional electrode overlaps the first region and the second region in plan view.

An acoustic wave device according to another example embodiment of the present invention includes a piezoelectric substrate including a piezoelectric layer, and a functional electrode at least a portion of which is embedded in the piezoelectric substrate. The piezoelectric substrate includes at least a first region and a second region with crystal structures different from each other, and the piezoelectric layer includes at least one of the first region and the second region.

With acoustic wave devices according to example embodiments of the present invention, a fractional band width is able to be readily adjusted.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view of an acoustic wave device according to a first example embodiment of the present invention.

FIG. 2 is a schematic sectional view taken along line I-I in FIG. 1.

FIG. 3 is a schematic sectional view taken along line II-II in FIG. 2.

FIG. 4A is a schematic diagram illustrating the crystal structure of a first region, and FIG. 4B is a schematic diagram illustrating the crystal structure of a second region.

FIG. 5 is a schematic elevational sectional view illustrating the vicinity of a pair of electrode fingers of an acoustic wave device according to a second example embodiment of the present invention.

FIG. 6 is a schematic elevational sectional view illustrating the vicinity of a pair of electrode fingers of an acoustic wave device according to a third example embodiment of the present invention.

FIG. 7 is a schematic sectional view taken along line III-III in FIG. 6.

FIG. 8 is a schematic elevational sectional view illustrating the vicinity of a pair of electrode fingers of an acoustic wave device according to a fourth example embodiment of the present invention.

FIG. 9 is a schematic elevational sectional view illustrating the vicinity of a pair of electrode fingers of an acoustic wave device according to a fifth example embodiment of the present invention.

FIG. 10 is a schematic elevational sectional view illustrating the vicinity of a pair of electrode fingers of an acoustic wave device according to a modified example of the fifth example embodiment of the present invention.

### DETAILED DESCRIPTION OF THE EXAMPLE EMBODIMENTS

The present invention will be clarified below by describing example embodiments of the present invention with reference to the drawings.

In this regard, each example embodiment described in the present specification is an exemplification, and it is to be noted that configurations described in different example embodiments can be partially replaced or combined with each other.

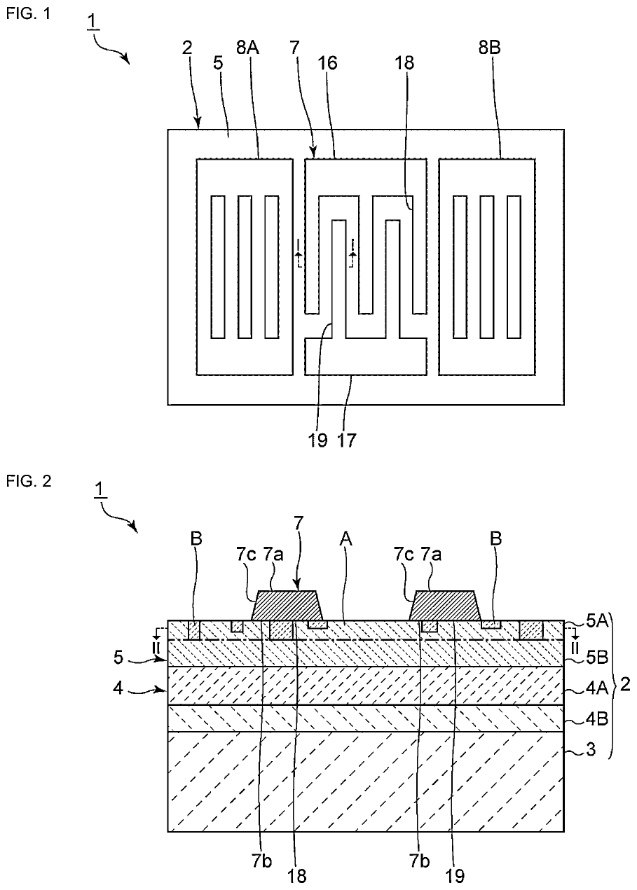

FIG. 1 is a schematic plan view of an acoustic wave device according to a first example embodiment of the present invention. FIG. 2 is a schematic sectional view taken along line I-I in FIG. 1.

As illustrated in FIG. 1 and FIG. 2, an acoustic wave device 1 includes a piezoelectric substrate 2. As illustrated in FIG. 2, the piezoelectric substrate 2 includes a support substrate 3, an intermediate layer 4, and a piezoelectric layer 5. That is, “piezoelectric substrate” means a substrate having piezoelectricity. Specifically, the support substrate 3, the intermediate layer 4, and the piezoelectric layer 5 are stacked in this order.

Each of the intermediate layer 4 and the piezoelectric layer 5 is a multilayer body. More specifically, the intermediate layer 4 includes a first intermediate layer 4A and a second intermediate layer 4B. The piezoelectric layer 5 includes a first piezoelectric layer 5A and a second piezoelectric layer 5B. The second intermediate layer 4B is disposed on the support substrate 3. The first intermediate layer 4A is disposed on the second intermediate layer 4B. The second piezoelectric layer 5B is disposed on the first intermediate layer 4A. The first piezoelectric layer 5A is disposed on the second piezoelectric layer 5B. In this regard, the intermediate layer 4 may include a single dielectric layer or the like. The piezoelectric layer 5 may include a single piezoelectric layer. Alternatively, the piezoelectric substrate 2 may include only the piezoelectric layer 5.

An interdigital transducer electrode 7 defining and functioning as a functional electrode, and a pair of reflector 8A and reflector 8B are disposed on the first piezoelectric layer 5A in the piezoelectric layer 5. An alternating-current voltage being applied to the functional electrode excites an acoustic wave. The acoustic wave device 1 according to the present example embodiment is, for example, a surface acoustic wave resonator. In this regard, acoustic wave devices according to example embodiments of the present invention may be, for example, a filter device or a multiplexer which includes a plurality of acoustic wave resonators.

As illustrated in FIG. 1, the interdigital transducer electrode 7 includes a first busbar 16, a second busbar 17, a plurality of first electrode fingers 18, and a plurality of second electrode fingers 19. The first busbar 16 and the second busbar 17 face each other. One end of each of the plurality of first electrode fingers 18 is connected to the first busbar 16. One end of each of the plurality of second electrode fingers 19 is connected to the second busbar 17. The plurality of first electrode fingers 18 and the plurality of second electrode fingers 19 are interdigitated with each other. The first electrode finger 18 and the second electrode finger 19 are coupled to potentials that differ from each other. Hereafter the first electrode finger 18 or the second electrode finger 19 is also referred to simply as the electrode finger. When the direction in which the plurality of electrode fingers extend is assumed to be an electrode finger extension direction, the electrode finger extension direction is orthogonal or substantially orthogonal to the acoustic wave propagation direction in the present example embodiment.

The reflector 8A and the reflector 8B face each other with the interdigital transducer electrode 7 interposed therebetween in the direction orthogonal or substantially orthogonal to the electrode finger extension direction.

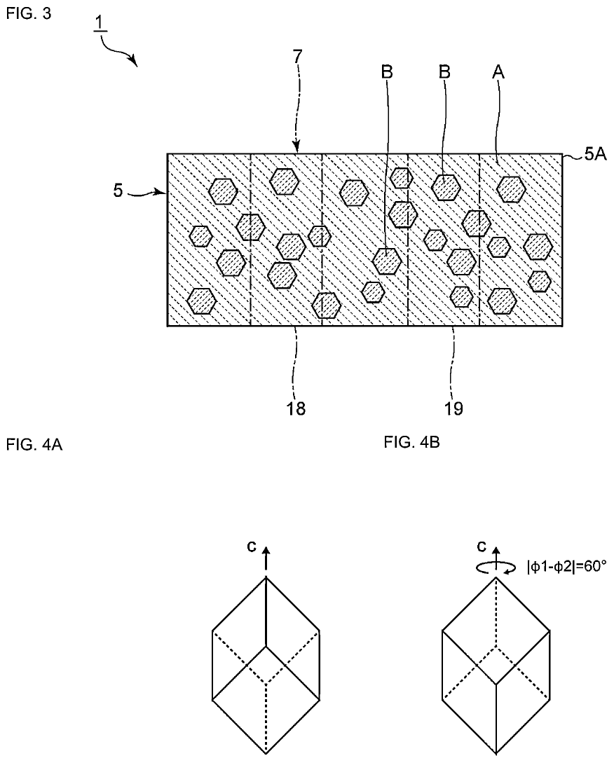

FIG. 3 is a schematic sectional view taken along line II-II in FIG. 2.

The first piezoelectric layer 5A includes a first region A and a second region B. The first region A and the second region B have crystal orientations that differ from each other. In this regard, the number of regions having crystal orientations that differ from each other is not limited to being two, that is, the first region A and the second region B and may be three or more. Hereafter, Euler angles of the first region are (Φ1,θ1,Ψ1), and Euler angles of the second region are (Φ2,θ2,Ψ2). Regarding the expression of Euler angles (Φ,θ,Ψ), a first Euler angle is Φ, a second Euler angle is θ, and a third Euler angle is W. In the present example embodiment, Φ1≠Φ2. That is, the first Euler angles of the first region A and the second region B differ from each other. More specifically, for example, the difference between Φ1 and Φ2 is about 60°. Meanwhile, θ1=θ2, and Ψ1=Ψ2. However, an aspect in which the crystal orientations of the first region A and the second region B differ from each other is not limited to the above. The difference between Φ1 and Φ2 may be other than about 60°. θ1≠θ2 or Ψ1≠Ψ2 may apply. That is, for example, the second Euler angles of the first region A and the second region B may differ from each other or the third Euler angles of the first region A and the second region B may differ from each other. In addition, when θ1≠θ2 or Ψ1≠Ψ2 applies, Φ1=θ2 may apply.

In this regard, with respect to the Euler angles (Φ1,θ1,Ψ1) of the first region A and the Euler angles (Φ2,θ2,Ψ2) of the second region B, it is known that even when each angle has a shift within the range of, for example, about ±5°, substantially no influence is exerted on the electric characteristics of the acoustic wave device 1. Accordingly, for example, in the present specification, when a difference in the Euler angles between the first region A and the second region B is within about ±5°, the two angles are assumed to be equal. For example, in the strict sense, even when Φ1 is within the range of, for example, Φ2±about 5°, it is assumed that Φ1=Φ2 applies. The same applies to the relationship between θ1 and θ2 and the relationship between Ψ1 and Ψ2.

As illustrated in FIG. 3, the first region A and the second region B are present together in the first piezoelectric layer 5A. In plan view of the first piezoelectric layer 5A, the area of the first region A is larger than the area of the second region B. Specifically, in the present example embodiment, the second region B is scattered in the first region A. However, one or more regions, such as a third region, for example, that are other than the first region A and the second region B and that have different crystallinity may be present. It is preferable that the one or more regions are present as many granular regions having a fine grain diameter at the interface between the first region A and the second region B or in both end portions, in the second region B, of the piezoelectric layer 5 in the thickness direction. Consequently, in the piezoelectric layer 5, strain and stress are reduced. On the other hand, the second piezoelectric layer 5B illustrated in FIG. 2 includes only the first region A. In the present specification, “in plan view” denotes to view the acoustic wave device from a position above in FIG. 2. In FIG. 2, for example, regarding the piezoelectric layer 5 side and the support substrate 3 side, the piezoelectric layer 5 side is the position above.

In the present example embodiment, the piezoelectric layer 5 includes the first region A and the second region B and the interdigital transducer electrode 7 overlaps the first region A and the second region B in plan view. As described above, the crystal orientations of the first region A and the second region B differ from each other. Accordingly, a phase shift of an excited acoustic wave occurs. Consequently, the electromechanical coupling coefficient in the present example embodiment differs from the electromechanical coupling coefficient when the piezoelectric layer 5 includes only the first region A. Therefore, a fractional band width can be readily adjusted by adjusting the ratio between the first region A and the second region B.

In this regard, when the piezoelectric layer 5 including the first region A and the second region B is obtained, for example, a piezoelectric layer including the first region A and the second region B may be formed by performing a film formation treatment on a wafer corresponding to a piezoelectric layer including only the first region A. In such an instance, a film including the second region B can be grown by partially disturbing the crystallinity of the wafer surface in advance through surface treatment, such as, for example, ion beam irradiation or plasma treatment, or reducing surface diffusion by, for example, decreasing the film formation temperature. The ratio between the first region A and the second region B can be adjusted by adjusting these process conditions or forming a resist pattern during the above-described surface treatment. Subsequently, the piezoelectric layer 5 of the acoustic wave device 1 is obtained by dividing the above-described wafer.

The configuration of the present example embodiment will be described below in further detail. To begin with, an example of the material for forming each layer in the piezoelectric substrate 2 illustrated in FIG. 2 will be described. In the present specification, a member being made of a material includes an instance in which a very small amount of impurity is included to such an extent that the electrical characteristics of the acoustic wave device do not significantly deteriorate. The primary component in the present specification denotes a component the proportion of which is more than about 50% by weight. The material defining and functioning as the above-described primary component may be present in a state of any one of a single crystal, a polycrystal, and an amorphous material or a state of a mixture of these.

Regarding first piezoelectric layer 5A and the second piezoelectric layer 5B in the piezoelectric layer 5, for example, lithium niobate such as LiNbO₃ or lithium tantalate such as LiTaO₃ which is an oxide piezoelectric body can be used. The first piezoelectric layer 5A and the second piezoelectric layer 5B according to the present example embodiment include, for example, lithium tantalate or lithium niobate which is a rhombohedral-system material. Therefore, the crystal structures of both the first region A and the second region B are the rhombohedral system. This is illustrated in FIG. 4A and FIG. 4B.

FIG. 4A is a schematic diagram illustrating the crystal structure of the first region, and FIG. 4B is a schematic diagram illustrating the crystal structure of the second region.

FIGS. 4A and 4B illustrate an example in which θ1 and θ2 in the Euler angles (Φ1, θ1, Ψ1) of the first region A and the Euler angles (Φ2, θ2, Ψ2) of the second region B are about 60°. In this regard, as described above, the difference between Φ1 and Φ2 is about 60°, and Ψ1=Ψ2. When Φ1≠Φ2, θ1=θ2, and Ψ1=Ψ2, the crystal structure of the second region B is a structure rotated around the c-axis defining and functioning as the center by an angle of the difference between Φ1 and Φ2 relative to the crystal structure of the first region A. Therefore, in the present example embodiment, the c-axes of the first region A and the second region B are parallel or substantially parallel to each other.

In this regard, when the first piezoelectric layer 5A and the second piezoelectric layer 5B include the rhombohedral-system material, it can also be said that the first piezoelectric layer 5A and the second piezoelectric layer 5B include a trigonal-system material.

In FIG. 2, for example, the first intermediate layer 4A in the intermediate layer 4 is a low-acoustic-velocity film in the present example embodiment. The low-acoustic-velocity film is a relatively low-acoustic-velocity film. More specifically, the acoustic velocity of a bulk wave propagating through the low-acoustic-velocity film is lower than the acoustic velocity of a bulk wave propagating through the first piezoelectric layer 5A and lower than the acoustic velocity of a bulk wave propagating through the second piezoelectric layer 5B. In the present example embodiment, the first intermediate layer 4A defining and functioning as the low-acoustic-velocity film includes silicon oxide, for example. However, the material for forming the low-acoustic-velocity film is not limited to the above, and, for example, glass, silicon oxide, silicon oxynitride, lithium oxide, tantalum oxide, or a dielectric such as a compound in which fluorine, carbon, or boron is added to silicon oxide, or a material including the above-described material as a primary component can be used.

The second intermediate layer 4B in the intermediate layer 4 is, for example, a high-acoustic-velocity film defining and functioning as a high-acoustic-velocity material layer in the present example embodiment. The high-acoustic-velocity material layer is a relatively high-acoustic-velocity film. More specifically, the acoustic velocity of a bulk wave propagating through the high-acoustic-velocity material layer is higher than the acoustic velocity of a bulk wave propagating through the first piezoelectric layer 5A and higher than the acoustic velocity of a bulk wave propagating through the second piezoelectric layer 5B. In the present example embodiment, the second intermediate layer 4B defining and functioning as the high-acoustic-velocity material layer includes silicon nitride, for example. However, the material for forming the high-acoustic-velocity material layer is not limited to the above, and, for example, a piezoelectric such as aluminum nitride, lithium tantalate, lithium niobate, or quartz, ceramic such as alumina, sapphire, magnesia, silicon nitride, silicon carbide, zirconia, cordierite, mullite, steatite, forsterite, spinel, or sialon, a dielectric such as aluminum oxide, silicon oxynitride, DLC (diamond-like carbon), or diamond, a semiconductor such as silicon, or a material including the above-described material as a primary component can also be used. In this regard, for example, the above-described spinel includes aluminum compounds including oxygen and at least one element selected from Mg, Fe, Zn, Mn, and the like. Examples of the spinel include MgAl₂O₄, FeAl₂O₄, ZnAl₂O₄, and MnAl₂O₄.

In the present example embodiment, the support substrate 3 includes silicon, for example. The azimuth of the principal surface of the support substrate 3 is (111), for example. However, the azimuth and the material for forming the support substrate 3 are not limited to the above. Regarding the material for forming the support substrate 3, for example, a piezoelectric such as aluminum nitride, lithium tantalate, lithium niobate, or quartz, ceramic such as alumina, sapphire, magnesia, silicon nitride, silicon carbide, zirconia, cordierite, mullite, steatite, forsterite, spinel, or sialon, a dielectric such as aluminum oxide, silicon oxynitride, DLC (diamond-like carbon), or diamond, or a semiconductor such as silicon, or a material including the above-described material as a primary component can also be used. In this regard, for example, the above-described spinel includes aluminum compounds including oxygen and at least one element selected from Mg, Fe, Zn, Mn, and the like. Examples of the spinel include MgAl₂O₄, FeAl₂O₄, ZnAl₂O₄, and MnAl₂O₄.

In the piezoelectric substrate 2, the second intermediate layer 4B defining and functioning as the high-acoustic-velocity material layer, the first intermediate layer 4A defining and functioning as the low-acoustic-velocity film, and the piezoelectric layer 5 are stacked in this order. Consequently, the energy of an acoustic wave can be effectively confined to the piezoelectric layer 5 side.

The interdigital transducer electrode 7, the reflector 8A, and the reflector 8B include Al, for example. However, the material for forming the interdigital transducer electrode 7 and each reflector is not limited to the above. The interdigital transducer electrode 7 and each reflector may include a multilayer metal film.

Examples of the design parameters of the acoustic wave device 1 according to the present example embodiment will be described below. Herein, a wavelength specified by the electrode finger pitch of the interdigital transducer electrode 7 is A. The electrode finger pitch is a center-to-center distance of adjoining electrode fingers coupled to potentials that differ from each other in the direction orthogonal or substantially orthogonal to the electrode finger extension direction. Specifically, λ=2p where the electrode finger pitch is p.
Interdigital transducer electrode 7; material Al, thickness about 0.2λ or less
First piezoelectric layer 5A; material LiNbO₃, region first region A and second region B present together, difference between Φ1 and Φ2 of about 60°, thickness about 0.66λ or less
Second piezoelectric layer 5B; material LiNbO₃, region only first region A, thickness about 0.34λ or more
Piezoelectric layer 5; total thickness about 1λ or less
First intermediate layer 4A; material SiO₂, thickness about 0.6λ or less
Second intermediate layer 4B; material SiN, thickness about 0.5λ or less
Support substrate 3; material Si, azimuth (111)
Wavelength Δ; about 5 μm

In this regard, for example, of the above-described design parameters, the material for forming the first piezoelectric layer 5A and the second piezoelectric layer 5B may be LiTaO₃.

Up to this point, the configuration in which two regions having crystal orientations that differ from each other are included in the piezoelectric layer has been described. In this regard, the configuration of example embodiments of the present invention is not limited to this. For example, in an example embodiment according to the present invention, the piezoelectric layer includes two regions in which crystal structures themselves differ from each other. When this configuration is provided in FIG. 2, the first piezoelectric layer 5A of the piezoelectric layer 5 includes the first region A and the second region B having crystal structures that differ from each other. Even such a configuration can differentiate, as in the first example embodiment, the electromechanical coupling coefficient from the electromechanical coupling coefficient when the piezoelectric layer 5 includes only the first region A. Therefore, the fractional band width can be readily adjusted. In this regard, the piezoelectric layer 5 may include three or more regions having crystal structures that differ from each other.

In particular, it is preferable that the piezoelectric layer 5 includes an oxide piezoelectric body, for example. The crystal structure of the oxide piezoelectric body includes an oxygen octahedron, for example. Consequently, even in the vicinity of the boundary between regions having crystal structures that differ from each other, mismatching between the regions is relaxed by the oxygen octahedron being distorted. Therefore, an epitaxial piezoelectric layer in which a plurality of crystal structures are present together is readily obtained. Specifically, examples of lithium niobate include, in addition to a LiNbO₃ type which is the most stable phase, an ilmenite type, LiNb₃O₈, Li₃NbO₄, LiNbO₂, Nb₂O₅, and Li₂O₂ which have different composition ratios, and NaNbO₃ and KNbO₃ which include a different element. Herein, examples of different crystal structures include a combination of the LiNbO₃ type and the ilmenite type and a combination of the LiNbO₃ type and the above-described compound having a different composition ratio. In this regard, the same applies to lithium tantalate.

The piezoelectric layer which includes two regions having crystal structures that differ from each other can be obtained by, for example, a method the same as or similar to the method for obtaining the piezoelectric layer which includes two regions having crystal orientations that differ from each other. For example, the piezoelectric layer which include two regions having crystal structures that differ from each other can be obtained by, for example, performing the above-described surface treatment and film formation.

In the present example embodiment, as illustrated in FIG. 3, the interdigital transducer electrode 7 overlaps the first region A and the second region B in plan view. Consequently, the electromechanical coupling coefficient can be effectively differentiated from the electromechanical coupling coefficient when the piezoelectric layer 5 includes only the first region A. Therefore, the fractional band width can be more reliably readily adjusted.

A preferable configuration of an example embodiment of the present invention will be described below. It is preferable that at least one electrode finger of the interdigital transducer electrode 7 overlaps the first region A and the second region B in plan view. For example, in the present example embodiment, as illustrated in FIG. 3, one first electrode finger 18 overlaps the first region A and the second region B in plan view. One second electrode finger 19 also overlaps the first region A and the second region B in plan view. Consequently, the fractional band width can be still more reliably readily adjusted.

It is preferable that the first region A and the second region B are present together. In such an instance, when the interdigital transducer electrode 7 is disposed on any portion of the first piezoelectric layer 5A, the configuration in which the interdigital transducer electrode 7 is disposed on the first region A and the second region B can be obtained. Therefore, the fractional band width can be more reliably readily adjusted, and the degree of design flexibility of the acoustic wave device 1 can be improved.

As illustrated in FIG. 2, it is preferable that the first piezoelectric layer 5A and the second piezoelectric layer 5B are directly stacked on one another. In this regard, it is preferable that the first piezoelectric layer 5A includes the first region A and the second region B and that the second piezoelectric layer 5B is a piezoelectric single-crystal layer including only the first region A. In such an instance, the first piezoelectric layer 5A can be readily formed by, for example, performing film formation treatment on the second piezoelectric layer 5B so as to epitaxially grow a layer composed of a piezoelectric material. However, the second piezoelectric layer 5B is not limited to being the piezoelectric single-crystal layer. When the second piezoelectric layer 5B includes only the first region A, the second piezoelectric layer 5B may include a very small amount of defects to such an extent that the electrical characteristics of the acoustic wave device 1 do not significantly deteriorate. In such an instance, the second piezoelectric layer 5B can be readily formed through liquid phase growth, for example.

It is preferable that the piezoelectric material of the first piezoelectric layer 5A and the second piezoelectric layer 5B are the same type. In such an instance, when the first piezoelectric layer 5A is epitaxially grown on a wafer corresponding to the second piezoelectric layer 5B, the crystallinity of the first piezoelectric layer 5A can be improved. Therefore, the electric characteristics of the acoustic wave device 1 can be improved. Specifically, for example, the Q value can be increased. In this regard, as described above, the piezoelectric layer 5 of the acoustic wave device 1 is obtained by dividing the wafer. Meanwhile, the same type of piezoelectric materials include piezoelectric materials that differ from each other in the crystallinity or the orientation. The same type of piezoelectric materials include piezoelectric materials where main elements of the respective piezoelectric materials are the same type and the composition ratios of the main elements differ from each other. For example, piezoelectric materials including Li, Nb, and O where composition ratios of Li, Nb, and O differ from each other are the same type of piezoelectric materials. In addition, when main elements of the respective piezoelectric materials are the same type and the respective piezoelectric materials are doped with a very small amount of impurity, the same type of piezoelectric materials include piezoelectric materials that differ from each other in the concentration of the impurity. Specifically, for example, when one lithium niobate and the other lithium niobate are doped with Fe, Mg, or the like at concentrations that differ from each other, the two piezoelectric materials are the same type of piezoelectric materials. Further, when main elements of one piezoelectric material and the other piezoelectric material are the same type, the one piezoelectric material is not doped with an impurity, and the other piezoelectric material is doped with a very small amount of impurity, the two piezoelectric materials are included in the same type of piezoelectric materials.

In the above-described example of the design parameters, the thickness of the second piezoelectric layer 5B is about 0.34λ or more, and the total thickness of the piezoelectric layer 5 is about 1λ or less. As described above, it is preferable that the thickness of the second piezoelectric layer 5B is about ⅓ or more of the total thickness of the piezoelectric layer 5. Further, it is more preferable that the thickness of the second piezoelectric layer 5B is about ½ or more of the total thickness of the piezoelectric layer 5. Consequently, the crystallinity of the piezoelectric layer 5 can be more reliably improved. In addition, since the thickness of the second piezoelectric layer 5B is large, in particular, the strength of the piezoelectric layer 5 in the first region A can be improved. Therefore, cracking can be reduced or prevented from occurring in the piezoelectric layer 5.

As illustrated in FIG. 3, a portion of the second region B is located between electrode fingers. Therefore, the value of the diameter of the second region B is smaller than the value of the electrode finger pitch. As described above, it is preferable that the maximum dimension in plan view of at least a portion of the second regions B included in the first piezoelectric layer 5A is smaller than the value of the electrode finger pitch. It is preferable that the maximum dimension in plan view of all of the second regions B included in the first piezoelectric layer 5A is smaller than the value of the electrode finger pitch. Consequently, regarding the acoustic wave device 1, acoustic wave excitation characteristics can be more reliably made uniform. Therefore, the electrical characteristics of the acoustic wave device 1 can be more reliably improved. In addition, the electric power handling capability can also be improved.

It is preferable that the total area of the first region A is larger than the total area of the second region B in plan view. In such an instance, the area of the second region B is readily adjusted. The example configurations described above can be applied to both of the instance in which the piezoelectric layer includes regions having crystal orientations that differ from each other and the instance in which the piezoelectric layer includes regions having crystal structures that differ from each other. The preferable configurations, described below, regarding the Euler angles can be appropriately applied to the instance in which the piezoelectric layer includes regions having crystal orientations that differ from each other.

Regarding the Euler angles (Φ1,θ1,Ψ1) of the first region A and the Euler angles (Φ2,θ2,Ψ2) of the second region B, it is preferable that Φ1≠Φ2, θ1=θ2, and Ψ1=Ψ2 apply. In such an instance, the c-axes of the first region A and the second region B are parallel or substantially parallel to each other. Consequently, the first region A and the second region B of the first piezoelectric layer 5A can be readily formed through epitaxial growth on the second piezoelectric layer 5B. In addition, the crystallinity of the first piezoelectric layer 5A can be improved, and the electric characteristics of the acoustic wave device 1 can be improved.

Regarding the Euler angles (Φ1,θ1,Ψ1) of the first region A and the Euler angles (Φ2,θ2,Ψ2) of the second region B, it is preferable that the difference between Φ1 and Φ2 is, for example, about 60°, about 180°, or about 300°. In such an instance, the crystal in the first region A and the crystal in the second region B are in the relationship of twin crystal. Therefore, the first region A and the second region B of the first piezoelectric layer 5A can be more readily formed through epitaxial growth on the second piezoelectric layer 5B. In addition, the crystallinity of the first piezoelectric layer 5A can be further improved, and the electric characteristics of the acoustic wave device 1 can be further improved.

For example, regarding the first region A and the second region B, Φ1≠Φ2 may apply and polarization directions may be opposite to each other. In such an instance, the c-axes of the first region A and the second region B are also parallel or substantially parallel to each other. Therefore, the first region A and the second region B of the first piezoelectric layer 5A can be readily formed through epitaxial growth on the second piezoelectric layer 5B. Herein, regarding the first region A and the second region B, “polarization directions are opposite to each other” means specifically an instance in which the difference between θ1 and θ2 is, for example, within about 180°+5°.

In the above, the example in which Φ1≠Φ2 applies regarding the Euler angles (Φ1,θ1,Ψ1) of the first region A and the Euler angles (Φ2,θ2,Ψ2) of the second region B is described as a preferable example. On the other hand, θ1≠θ2 is also preferable. In this regard, θ1≠θ2 means that the polarization directions in the first region A and the second region B differ from each other. When the polarization directions of the two regions differ from each other, the directions of the c-axes differ from each other except the instance in which the polarization directions are opposite to each other.

In this regard, in the instance in which θ1≠θ2 is intended, for example, when film formation treatment is performed on the wafer corresponding to the second piezoelectric layer 5B, it is sufficient that the wafer is irradiated with an ion beam before film formation is performed. Alternatively, for example, when film formation is performed by sputtering, it is sufficient that a milling effect due to self bias is used. Consequently, a preferential orientation plane can be controlled so as to readily incline the polarization direction of the second region B relative to the polarization direction of the first region A. More specifically, for example, when LiNbO₃ is used for the first piezoelectric layer 5A and the second piezoelectric layer 5B, due to ion irradiation in the direction normal or substantially normal to the wafer, growth tends to occur while the crystal c-axis direction is inclined relative to the direction normal or substantially normal to the wafer, and a crystal grain with an inclined polarization direction appears.

It is preferable that the polarization directions of the first region A and the second region B are opposite to each other. Accordingly, a phase shift of an excited acoustic wave can be readily caused. Consequently, the fractional band width can be more readily adjusted.

The preferable configuration described below can be applied to both of the instance in which the piezoelectric layer has regions having crystal orientations that differ from each other and the instance in which the piezoelectric layer has regions having crystal structures that differ from each other. It is preferable that the piezoelectric layer 5 includes, for example, lithium tantalate or lithium niobate which is a rhombohedral-system or trigonal-system material. In such an instance, even when the first region A and the second region B are included, the electromechanical coupling coefficient can be more reliably increased. Therefore, the electrical characteristics of the acoustic wave device 1 can be more reliably improved.

As illustrated in FIG. 2, the sectional shape of each electrode finger of the interdigital transducer electrode 7 is a trapezoid, for example. Specifically, each electrode finger includes a first surface 7a, a second surface 7b, and a side surface 7c. The first surface 7a and the second surface 7b face each other in the thickness direction of the electrode finger. Of the first surface 7a and the second surface 7b, the second surface 7b is located on the piezoelectric layer 5 side and is located on the support substrate 3 side. The side surface 7c is connected to the first surface 7a and the second surface 7b. The side surface 7c extends inclining relative to the direction normal or substantially normal to the second surface 7b. However, the side surface 7c of each electrode finger may extend parallel or substantially parallel to the direction normal or substantially normal to the second surface 7b.

In this regard, a protective film may be disposed on the piezoelectric layer 5 so as to cover the interdigital transducer electrode 7. In such an instance, the interdigital transducer electrode 7 is less likely to be damaged. Regarding the protective film, for example, silicon oxide, silicon nitride, or silicon oxynitride can be used. This configuration can also be applied to example embodiments according to the present invention other than the first example embodiment.

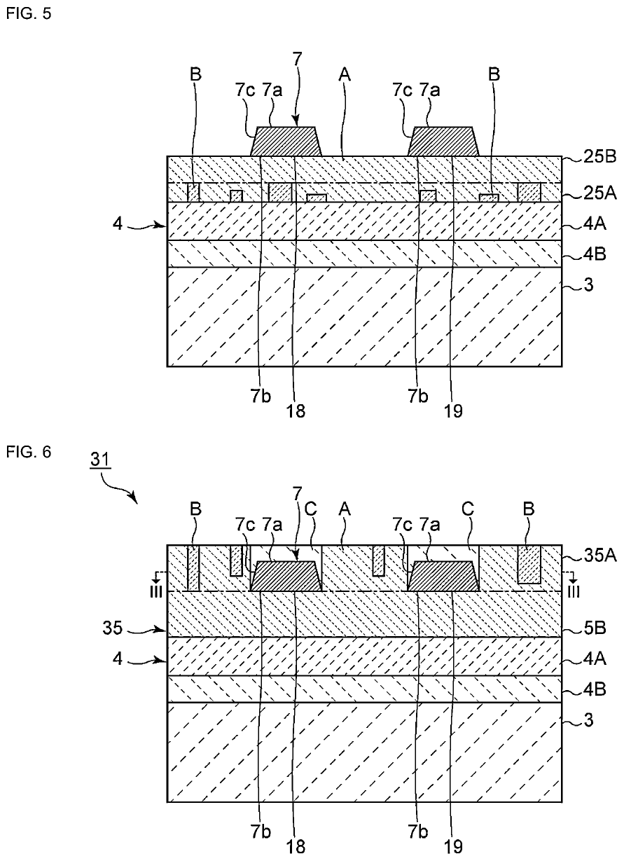

FIG. 5 is a schematic elevational sectional view illustrating the vicinity of a pair of electrode fingers of an acoustic wave device according to a second example embodiment of the present invention.

The present example embodiment differs from the first example embodiment in the order of stacking of a first piezoelectric layer 25A and a second piezoelectric layer 25B. Specifically, the first piezoelectric layer 25A is disposed on the intermediate layer 4. The second piezoelectric layer 25B is disposed on the first piezoelectric layer 25A. The interdigital transducer electrode 7 is disposed on the second piezoelectric layer 25B. Except for the above points, the acoustic wave device according to the present example embodiment has a configuration the same as or similar to the configuration of the acoustic wave device 1 according to the first example embodiment.

In the present example embodiment, the interdigital transducer electrode 7 is disposed on the second piezoelectric layer 25B that includes a single phase. In such an instance, the interdigital transducer electrode 7 is readily formed through epitaxial growth. Therefore, the electric power handling capability can be more reliably improved. In addition, as in the first example embodiment, the fractional band width can be readily adjusted by adjusting the ratio between the first region A and the second region B.

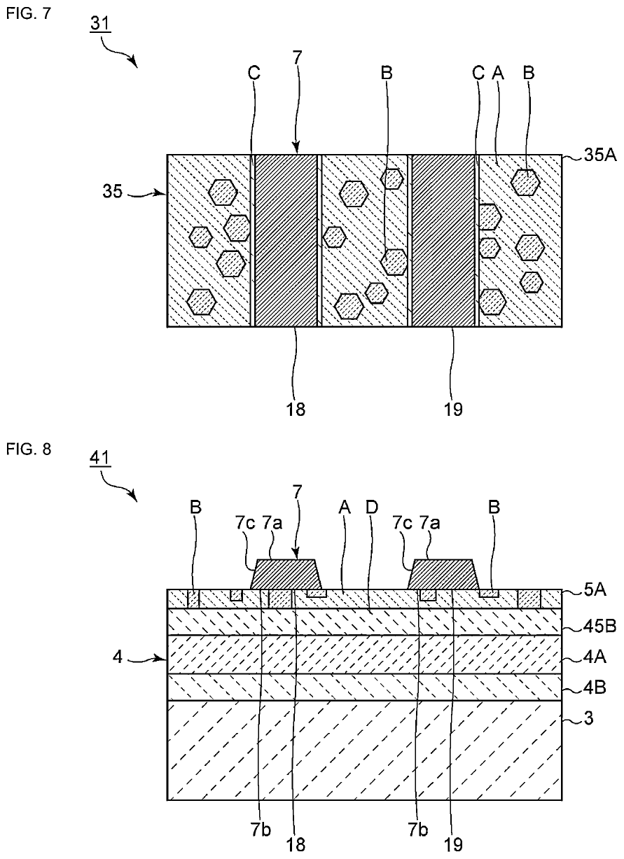

FIG. 6 is a schematic elevational sectional view illustrating the vicinity of a pair of electrode fingers of an acoustic wave device according to a third example embodiment of the present invention. FIG. 7 is a schematic sectional view taken along line III-III in FIG. 6.

As illustrated in FIG. 6, the present example embodiment differs from the first example embodiment in that the interdigital transducer electrode 7 is embedded in a piezoelectric layer 35 and that a portion covering the side surface 7c and the first surface 7a of each electrode finger of the interdigital transducer electrode 7 is a third region C. Specifically, a plurality of electrode fingers of the interdigital transducer electrode 7 are embedded in a first piezoelectric layer 35A of the piezoelectric layer 35. Except for the above points, an acoustic wave device 31 according to the present example embodiment has a configuration the same as or similar to the configuration of the acoustic wave device 1 according to the first example embodiment.

In the piezoelectric layer 35, the third region C is an amorphous phase region. In this regard, the third region C may have a crystal structure. In such an instance, the crystal orientation of the third region C differs from the crystal orientations of the first region A and the second region B. Alternatively, the crystal structure of the third region C differs from the crystal structures of the first region A and the second region B.

When the piezoelectric layer 35 according to the present example embodiment is formed, for example, after the second piezoelectric layer 5B is formed, the interdigital transducer electrode 7 is formed on the second piezoelectric layer 5B. Thereafter, for example, the first piezoelectric layer 35A may be formed by performing film formation on the second piezoelectric layer 5B and the interdigital transducer electrode 7. When the film formation is performed, due to an influence of the crystallinity of the interdigital transducer electrode 7, the third region C becomes a region having a crystal orientation that differs from the crystal orientations of the first region A and the second region B, a region having a crystal structure that differs from the crystal structures of the first region A and the second region B, or a region of an amorphous phase. Herein, examples of the design parameters of the acoustic wave device 31 will be described below.
Interdigital transducer electrode 7; layer configuration Pt layer/Al layer from second piezoelectric layer 5B side, total thickness about 0.4λ or less
First piezoelectric layer 35A; material LiNbO₃, region first region A and second region B present together, difference between Φ1 and Φ2 of about 60°, amorphous phase third region C covering interdigital transducer electrode 7
Second piezoelectric layer 5B; material LiNbO₃, region only first region A
Piezoelectric layer 35; total thickness about 0.6λ or less
First intermediate layer 4A; material SiO₂, thickness about 0.6λ or less
Second intermediate layer 4B; material SiN, thickness about 0.5λ or less
Support substrate 3; material Si, azimuth (111)

In this regard, for example, in the above-described design parameters, the material for forming the first piezoelectric layer 35A and the second piezoelectric layer 5B may be LiTaO₃. In the above-described example of the design parameters, the interdigital transducer electrode 7 includes the multilayer metal film, but the interdigital transducer electrode 7 may include a single-layer metal film.

The acoustic wave device 31 has a configuration in which each electrode finger of the interdigital transducer electrode 7 is embedded in the piezoelectric layer 35. Consequently, the electrostatic capacitance can be increased. Therefore, when predetermined electrostatic capacitance is obtained, the acoustic wave device 31 can be reduced in size.

In the present example embodiment, as in the first example embodiment, the crystal orientations of the first region A and the second region B differ from each other. Accordingly, a phase shift occurs in an excited acoustic wave. Consequently, the electromechanical coupling coefficient in the present example embodiment differs from the electromechanical coupling coefficient when the piezoelectric layer 35 includes only the first region A. The fractional band width can be readily adjusted by adjusting the ratio between the first region A and the second region B.

In this regard, when the third region C is a region having a crystal orientation that differs from the crystal orientations of the first region A and the second region B, the electromechanical coupling coefficient can be effectively differentiated from the electromechanical coupling coefficient when the piezoelectric layer 35 includes only the first region A. Therefore, the fractional band width can be more reliably readily adjusted by adjusting the ratio between the first region A and the second region B.

It is sufficient that at least a portion of the plurality of electrode fingers are embedded in the piezoelectric layer 35. However, it is preferable that, as in the present example embodiment, all of the plurality of electrode fingers are embedded in the piezoelectric layer 35. Consequently, in the acoustic wave device 31, the electrostatic capacitance can be appropriately increased.

FIG. 8 is a schematic elevational sectional view illustrating the vicinity of a pair of electrode fingers of an acoustic wave device according to a fourth example embodiment of the present invention.

The present example embodiment differs from the first example embodiment in that a second piezoelectric layer 45B includes only a fourth region D. On the other hand, as in the first example embodiment, the first piezoelectric layer 5A includes the first region A and the second region B. A piezoelectric material of the fourth region D differs from the piezoelectric material of the first region A and the second region B. Except for the above points, an acoustic wave device 41 according to the present example embodiment has a configuration the same as or similar to the configuration of the acoustic wave device 1 according to the first example embodiment.

In the acoustic wave device 41, specifically, the first piezoelectric layer 5A includes lithium tantalate, for example. Accordingly, the piezoelectric material of the first region A and the second region B is lithium tantalate, for example. On the other hand, the second piezoelectric layer 45B includes lithium niobate, for example. Accordingly, the piezoelectric material of the fourth region D is lithium niobate, for example. The crystal orientations of the first region A and the fourth region D are the same. Consequently, the first piezoelectric layer 5A is readily formed through epitaxial growth on the second piezoelectric layer 45B. In this regard, the crystal orientations of the first region A and the fourth region D are not limited to being the same. Regarding combinations of the materials for forming the first piezoelectric layer 5A and the second piezoelectric layer 45B, for example, the material for forming the first piezoelectric layer 5A may be lithium niobate, and the material for forming the second piezoelectric layer 45B may be lithium tantalate. Alternatively, combinations of other piezoelectric materials may be used.

In the present example embodiment, as in the first example embodiment, the fractional band width can be readily adjusted by adjusting the ratio between the first region A and the second region B. In addition, since the piezoelectric materials of the first piezoelectric layer 5A and the second piezoelectric layer 45B differ from each other, the range of adjustment of the electrical characteristics of the acoustic wave device 41 can be readily increased.

In this regard, the acoustic wave devices according to the second example embodiment to fourth example embodiment of the present invention may have a configuration in which the crystal structures of the first region A and the second region B differ from each other.

In the first example embodiment and the like, the first piezoelectric layer includes both the first region A and the second region B. Therefore, the first region A and the second region B include the same type of material. In this regard, in the present invention, it is sufficient that the piezoelectric substrate includes at least the first region A and the second region B. It is sufficient that the piezoelectric layer includes at least one of the first region A and the second region B. For example, an insulator layer that is not a piezoelectric layer may include one of the first region A and the second region B. This example is described with reference to a fifth example embodiment of the present invention.

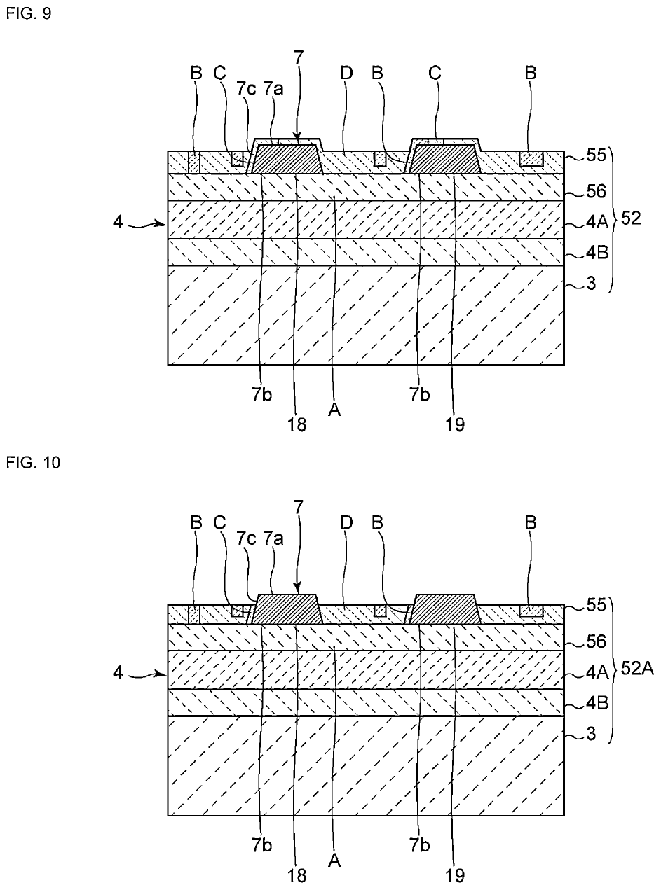

FIG. 9 is a schematic elevational sectional view illustrating the vicinity of a pair of electrode fingers of an acoustic wave device according to the fifth example embodiment.

The present example embodiment differs from the first example embodiment in the layer configuration of a piezoelectric substrate 52, the arrangement of each region in the piezoelectric substrate 52, and the arrangement of the interdigital transducer electrode 7. Except for the above points, the acoustic wave device according to the present example embodiment has a configuration the same as or similar to the configuration of the acoustic wave device 1 according to the first example embodiment.

The piezoelectric substrate 52 differs from the piezoelectric substrate 2 according to the first example embodiment in that an insulator layer 56 is included and that a piezoelectric layer 55 includes a single layer. Specifically, in the piezoelectric substrate 52, the second intermediate layer 4B is disposed on the support substrate 3. The first intermediate layer 4A is disposed on the second intermediate layer 4B. The insulator layer 56 is disposed on the first intermediate layer 4A. The piezoelectric layer 55 is disposed on the insulator layer 56.

In the present example embodiment, the material of the insulator layer 56 is not a piezoelectric material. However, the material of the insulator layer 56 may be a piezoelectric material. When the material of the insulator layer 56 is not a piezoelectric material, for example, sapphire, can be used as the material of the insulator layer 56.

The interdigital transducer electrode 7 is disposed on the insulator layer 56. As illustrated in FIG. 9, the piezoelectric layer 55 is disposed on the insulator layer 56 so as to cover the entire or substantially the entire interdigital transducer electrode 7. That is, the second surface 7b of each electrode finger of the interdigital transducer electrode 7 is in contact with the insulator layer 56. On the other hand, the first surface 7a and the side surface 7c of each electrode finger are in contact with the piezoelectric layer 55. In such an instance, an acoustic wave is excited by applying an alternating-current voltage to the interdigital transducer electrode 7.

The insulator layer 56 includes the first region A. Meanwhile, the piezoelectric layer 55 includes the second region B, the third region C, and the fourth region D. In the piezoelectric layer 55, the second region B, the third region C, and the fourth region D are present together. Specifically, in plan view of the piezoelectric layer 55, the total area of the fourth region D is larger than the total area of the second region B. More specifically, in the present example embodiment, the second regions B are scattered in the fourth region D.

In plan view, the total area of the fourth region D is larger than the total area of the third region C. More specifically, the third region C is located in at least a portion of a portion of the piezoelectric layer 55 covering the electrode fingers. In more detail, in the present example embodiment, the third region C is located in a portion of the portion of the piezoelectric layer 55 covering the electrode fingers. The second region B and the fourth region D are located in another portion of the portion of the piezoelectric layer 55 covering the electrode fingers. However, the third region C may be located in the entire or substantially the entire portion of the piezoelectric layer 55 covering the electrode fingers.

As described above, the piezoelectric substrate includes the third region C, and the third region C covers at least a portion of the interdigital transducer electrode 7 defining and functioning as a functional electrode. This configuration can also be applied to the configuration in which, as in the first example embodiment and the like, the piezoelectric layer is a multilayer body.

In the piezoelectric substrate 52 according to the present example embodiment, the crystal orientation of the first region A and the crystal orientation of the second region B differ from each other. The fractional band width can be readily adjusted by adjusting the ratio between the first region A and the second region B.

In this regard, in the piezoelectric substrate 52, the crystal structure of the first region A and the crystal structure of the second region B may differ from each other. In such an instance, the fractional band width can also be readily adjusted by adjusting the ratio between the first region A and the second region B.

The third region C in the piezoelectric substrate 52 has a crystal structure. The crystal orientation of the third region C differs from the crystal orientations of the first region A and the second region B. However, the crystal structure of the third region C may differ from the crystal structures of the first region A and the second region B. Alternatively, the third region C may be an amorphous phase region, for example.

In the piezoelectric layer 55 of the piezoelectric substrate 52, the crystal orientation of the second region B and the crystal orientation of the fourth region D differ from each other. In example embodiments of the present invention, the fourth region D located in the piezoelectric layer 55 may be the first region. The first region A located in the insulator layer 56 may be the fourth region. In such an instance, the fractional band width can also be readily adjusted by adjusting the ratio between the first region serving as the fourth region D located in the piezoelectric layer 55 and the second region B.

The crystal structure of the first region defining and functioning as the fourth region D located in the piezoelectric layer 55 and the crystal structure of the second region B may differ from each other. In such an instance, the fractional band width can also be readily adjusted by adjusting the ratio between the first region defining and functioning as the fourth region D located in the piezoelectric layer 55 and the second region B.

It is sufficient that the piezoelectric layer 55 covers at least a portion of the interdigital transducer electrode 7. In other words, it is sufficient that at least a portion of the interdigital transducer electrode 7 is embedded in the piezoelectric substrate 52. For example, in a modified example of the fifth example embodiment illustrated in FIG. 10, the piezoelectric layer 55 covers a portion of the interdigital transducer electrode 7. Specifically, the piezoelectric layer 55 is disposed on the insulator layer 56 so as to cover a portion of the side surface 7c of each electrode finger. The first surface 7a of each electrode finger is not covered with the piezoelectric layer 55. As described above, a portion of the interdigital transducer electrode 7 is embedded in a piezoelectric substrate 52A. In such an instance, an acoustic wave is also excited by applying an alternating-current voltage to the interdigital transducer electrode 7.

In the present modified example, as in the fifth example embodiment, the insulator layer 56 of the piezoelectric substrate 52A includes the first region A. The piezoelectric layer 55 includes the second region B, the third region C, and the fourth region D. In the piezoelectric substrate 52A, the crystal orientation of the first region A and the crystal orientation of the second region B differ from each other. The fractional band width can be readily adjusted by adjusting the ratio between the first region A and the second region B.

In the piezoelectric substrate 52A, the crystal structure of the first region A and the crystal structure of the second region B may differ from each other. In such an instance, the fractional band width can also be readily adjusted by adjusting the ratio between the first region A and the second region B.

The above-described first example embodiment to the modified example of the fifth example embodiment describe examples in which the functional electrode is the interdigital transducer electrode, and the acoustic wave device is the surface acoustic wave device. However, the functional electrode is not limited to the interdigital transducer electrode. For example, the functional electrode may be a plate electrode or the like. In such an instance, the acoustic wave device may be a BAW (Bulk Acoustic Wave) element.

More specifically, for example, the functional electrode may be a first plate electrode and a second plate electrode. For example, the first plate electrode and the second plate electrode may face each other with the piezoelectric layer 5 illustrated in FIG. 2 interposed therebetween. It is preferable that the first plate electrode and the second plate electrode overlap the first region A and the second region B in plan view.

Alternatively, for example, at least a portion of at least one of the first plate electrode and the second plate electrode may be embedded in the piezoelectric layer 35 illustrated in FIG. 6. It is sufficient that the first plate electrode and the second plate electrode face each other with a portion of the piezoelectric layer 35 in the thickness direction interposed therebetween. In such an instance, the third region C may be located in a portion of the piezoelectric layer 35 covering the first plate electrode and the second plate electrode. The third region C may be an amorphous phase region or may have a crystal structure. When the third region C has a crystal structure, the crystal orientation of the third region C differs from the crystal orientations of the first region A and the second region B. Alternatively, the crystal structure of the third region C differs from the crystal structures of the first region A and the second region B.

When the functional electrode is the plate electrode, it is sufficient that the crystal orientation of the first region A and the crystal orientation of the second region B differ from each other. Alternatively, it is sufficient that the crystal structure of the first region A and the crystal structure of the second region B differ from each other. The fractional band width can be readily adjusted by adjusting the ratio between the first region A and the second region B.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate including a piezoelectric layer; and
a functional electrode on the piezoelectric layer and including a plurality of electrode fingers; wherein
the piezoelectric layer includes at least a first region and a second region with crystal orientations different from each other; and
the functional electrode overlaps the first region and the second region in plan view.

2. An acoustic wave device comprising:
a piezoelectric substrate including a piezoelectric layer; and
a functional electrode including at least a portion thereof embedded in the piezoelectric substrate; wherein
the piezoelectric substrate includes at least a first region and a second region with crystal orientations different from each other; and
the piezoelectric layer includes at least one of the first region and the second region.

3. An acoustic wave device comprising:
a piezoelectric substrate including a piezoelectric layer; and
a functional electrode on the piezoelectric layer and including a plurality of electrode fingers; wherein
the piezoelectric layer includes at least a first region and a second region with crystal structures different from each other; and
the functional electrode overlaps the first region and the second region in plan view.

4. An acoustic wave device comprising:
a piezoelectric substrate including a piezoelectric layer; and
a functional electrode including at least a portion thereof embedded in the piezoelectric substrate; wherein
the piezoelectric substrate includes at least a first region and a second region with crystal structures different from each other; and
the piezoelectric layer includes at least one of the first region and the second region.

5. The acoustic wave device according to claim 1, wherein
the functional electrode is an interdigital transducer electrode including a plurality of electrode fingers; and
at least one of the plurality of electrode fingers of the interdigital transducer electrode overlaps the first region and the second region in plan view.

6. The acoustic wave device according to claim 2, wherein the functional electrode is an interdigital transducer electrode including a plurality of electrode fingers.

7. The acoustic wave device according to claim 2, wherein
the piezoelectric substrate includes a third region covering at least a portion of the functional electrode; and
the third region is an amorphous phase region or a region with a crystal orientation different from the crystal orientations of the first region and the second region.

8. The acoustic wave device according to claim 1, wherein
polarization directions of the first region and the second region are different from each other.

9. The acoustic wave device according to claim 8, wherein
the polarization directions of the first region and the second region are opposite to each other.

10. The acoustic wave device according to claim 1, wherein Φ1≠Φ2, where Euler angles of the first region are (Φ1,θ1,Ψ1), and Euler angles of the second region are (Φ2,θ2,Ψ2).

11. The acoustic wave device according to claim 10, wherein a difference between Φ1 and Φ2 is about 60°, about 180°, or about 300°.

12. The acoustic wave device according to claim 3, wherein
the functional electrode is an interdigital transducer electrode including a plurality of electrode fingers; and
at least one of the plurality of electrode fingers of the interdigital transducer electrode overlaps the first region and the second region in plan view.

13. The acoustic wave device according to claim 4, wherein
the functional electrode is an interdigital transducer electrode including a plurality of electrode fingers.

14. The acoustic wave device according to claim 4, wherein
the piezoelectric substrate includes a third region covering at least a portion of the functional electrode; and
the third region is an amorphous phase region or a region with a crystal structure different from the crystal structures of the first region and the second region.

15. The acoustic wave device according to claim 1, wherein
the piezoelectric layer includes an oxide piezoelectric body.

16. The acoustic wave device according to claim 1, wherein
the piezoelectric layer includes lithium tantalate or lithium niobate.

17. The acoustic wave device according to claim 1, wherein the piezoelectric layer includes at least one layer in which the first region and the second region are included in combination.

18. The acoustic wave device according to claim 17, wherein
the piezoelectric layer is a multilayer body including at least a first piezoelectric layer and a second piezoelectric layer; and
the first region and the second region are located together in the first piezoelectric layer.

19. The acoustic wave device according to claim 18, wherein the second piezoelectric layer includes the first region.

20. The acoustic wave device according to claim 19, wherein a thickness of the second piezoelectric layer is about ½ or more of a total thickness of the piezoelectric layer.

21. The acoustic wave device according to claim 18, wherein
the first region and the second region include a same type of piezoelectric material; and
the second piezoelectric layer includes only a fourth region including a piezoelectric material different from the piezoelectric material of the first region and the second region.

22. The acoustic wave device according to claim 17, wherein the first region and the second region include a same type of piezoelectric material.

23. The acoustic wave device according to claim 17, wherein a total area of the first region is larger than a total area of the second region in plan view of the piezoelectric layer.
